(19) United States
(12) Patent Application Publication
(10) Pub. No.: US 2025/0234760 A1
(43) Pub. Date: Jul. 17, 2025

(54) LIGHT EMITTING DEVICE, IMAGE FORMING DEVICE, DISPLAY DEVICE, PHOTOELECTRIC CONVERSION DEVICE, AND ELECTRONIC APPARATUS

(71) Applicant: CANON KABUSHIKI KAISHA, Tokyo (JP)

(72) Inventor: SHOMA HINATA, Kanagawa (JP)

(21) Appl. No.: 19/013,149

(22) Filed: Jan. 8, 2025

(30) Foreign Application Priority Data
Jan. 17, 2024 (JP) 2024-005557

(51) Int. Cl. H10K 59/80

(52) U.S. Cl. CPC H10K 59/879

(57) ABSTRACT

A light emitting device with a plurality of light emitting elements arranged on a main surface of a substrate is provided. Each of the plurality of light emitting elements includes a light emitter and a lens, and a surface of the lens includes a convex portion that has a convex bulge extending continuously in a direction along the main surface and has positive power, and a concave portion surrounded by the convex portion.

### BACKGROUND OF THE INVENTION

### Field of the Invention

The present invention relates to a light emitting device, an image forming device, a display device, a photoelectric conversion device, and an electronic apparatus.

### Description of the Related Art

Japanese Patent Laid-Open No. 2016-122612 describes that a lens is arranged on a light emitter and the shape of the lens and the distance between the lens and the light emitter are adjusted to improve the light-extraction efficiency in a light emitting device.

### SUMMARY OF THE INVENTION

To improve the performance of a light emitting device, it is necessary to further efficiently extract light emitted from a light emitter.

Some embodiments of the present invention provide a technique advantageous in improving the light-extraction efficiency.

According to some embodiments, a light emitting device with a plurality of light emitting elements arranged on a main surface of a substrate, wherein each of the plurality of light emitting elements includes a light emitter and a lens, and a surface of the lens includes a convex portion that has a convex bulge extending continuously in a direction along the main surface and has positive power, and a concave portion surrounded by the convex portion, is provided.

According to some other embodiments, a light emitting device with a plurality of light emitting elements arranged on a main surface of a substrate, wherein each of the plurality of light emitting elements includes a light emitter and a lens, and a surface of the lens includes a convex portion that has a convex bulge extending continuously in a direction along the main surface and has positive power, and a first concave portion and a second concave portion adjacent to each other via the convex portion, a maximum angle of the surface with respect to the main surface between a portion of the convex portion where a tangent thereof is parallel to the main surface and a portion of the second concave portion that is closest to the main surface is smaller than a maximum angle of the surface with respect to the main surface between the parallel portion and a portion of the first concave portion that is closest to the main surface, and in an orthogonal projection to the main surface, the first concave portion is arranged at a position closer to a center of the light emitter than the second concave portion, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a light emitting device according to an embodiment;

FIG. 2 is a view showing an example of the arrangement of a light emitting device according to a comparative example;

FIG. 3 is a view showing an example of the arrangement of the light emitting device shown in FIG. 1;

FIG. 4 is a view showing an example of the arrangement of the light emitting device shown in FIG. 1;

FIG. 5 is a view showing an example of the arrangement of the light emitting device shown in FIG. 1;

FIG. 6 is a view showing an example of the arrangement of the light emitting elements of the light emitting device shown in FIG. 1;

FIG. 7 is a view showing an example of the arrangement of the light emitting elements of the light emitting device shown in FIG. 1;

FIG. 8 is a view showing an example of the arrangement of the light emitting elements of the light emitting device shown in FIG. 1;

FIG. 9 is a view showing an example of the arrangement of the light emitting device according to the embodiment;

FIG. 10 is a view showing an example of the arrangement of the light emitting device according to the embodiment;

FIGS. 11A to 11C are views showing an example of an image forming device using the light emitting device according to the embodiment;

FIG. 12 is a view showing an example of a display device using the light emitting device according to the embodiment;

FIG. 13 is a view showing an example of a photoelectric conversion device using the light emitting device according to the embodiment;

FIG. 14 is a view showing an example of an electronic apparatus using the light emitting device according to the embodiment;

FIGS. 15A and 15B are views each showing an example of a display device using the light emitting device according to the embodiment;

FIG. 16 is a view showing an example of an illumination device using the light emitting device according to the embodiment;

FIG. 17 is a view showing an example of a moving body using the light emitting device according to the embodiment; and

FIGS. 18A and 18B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

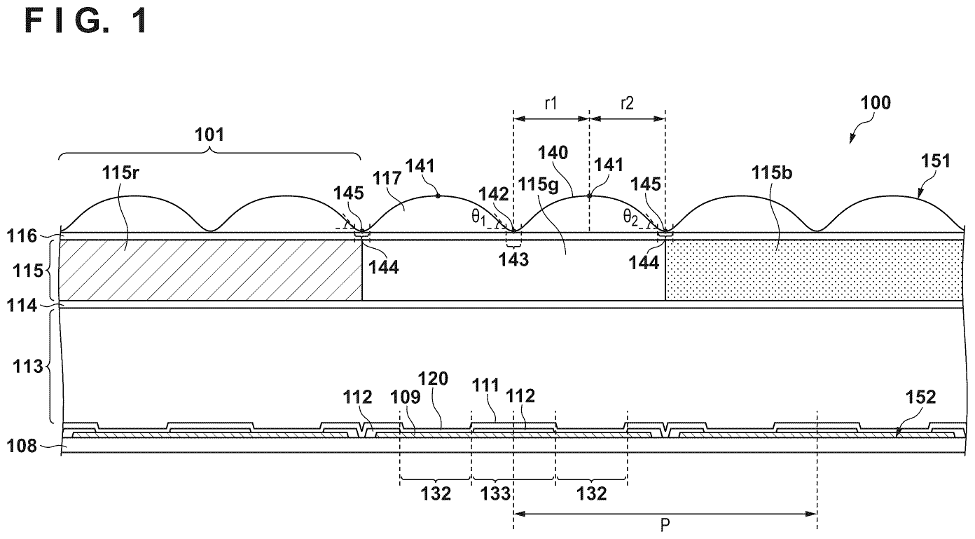

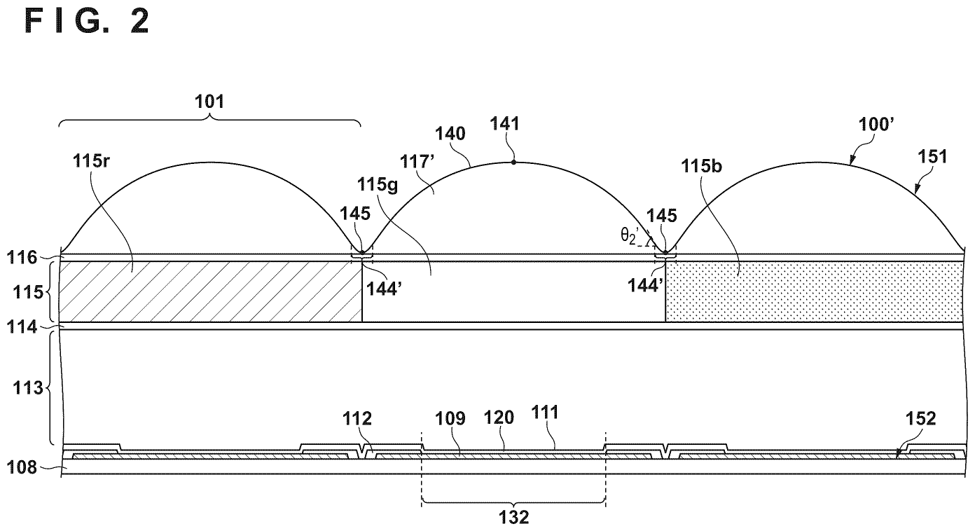

With reference to FIGS. 1 to 10, a light emitting device according to an embodiment of the present disclosure will be described. FIG. 1 is a sectional view showing an example of the arrangement of a lens 117 arranged in a light emitting device 100 according to this embodiment. FIG. 2 is a sectional view showing an example of the arrangement of a lens 117′ arranged in a light emitting device 100′ according to a comparative example. In the light emitting device 100, a plurality of light emitting elements 101 are arranged on a main surface 152 of a substrate 108. Each of the plurality of light emitting elements 101 includes a light emitter 132 and the lens 117. The example shown in FIG. 1 shows an organic light emitting element that includes, as the light emitter 132, an electrode 109 (to be also referred to as a lower electrode or the like), an organic layer 120 including a light emitting layer, and an electrode 111 (to be also referred to as an upper electrode or the like). However, the present invention is not limited to this and, for example, a light emitting element that contains, as the light emitter 132, an inorganic light emitting material or quantum dots may be used, or a light emitting diode or the like may be used. For example, a so-called micro LED may be used as the light emitter 132. Details of the light emitting element 101 and an insulating layer 112, a protection layer 113, a planarizing layer 114, a color filter 115, a planarizing layer 116, and the like included in the light emitting element 101 will be described later.

The lens 117 can also be called a microlens or the like. A surface 151 (to be also referred to as an upper surface or the like) of the lens 117 includes a convex portion 140 having a convex shape in a direction away from the main surface 152 of the substrate 108. The convex portion 140 is a portion of the surface 151 of the lens 117 where a convex bulge extends continuously in a direction along the main surface 152 of the substrate 108. Light emitted in an outward direction (a direction away from the center of the light emitter 132 in an orthogonal projection to the main surface 152 of the substrate 108) from the light emitter 132 can be converted into parallel light (collimated light) by refraction on the convex portion 140 of the lens 117, and extracted in a direction (front direction) perpendicular to the main surface 152 of the substrate 108. That is, the lens 117 can function as a collimator. The convex portion 140 of the lens 117 may have a light-harvesting property. The convex portion 140 of the lens 117 can have positive power for converting light emitted from the light emitter 132 into parallel light or converging light.

The convex portion 140 includes a vertex portion 141. The vertex portion 141 of the convex portion 140 can be a portion of the surface 151 of the lens 117 that is farthest from the main surface 152 of the substrate 108. The vertex portion 141 may be a set of points where the distance from the main surface 152 of the substrate 108 is maximum. Alternatively, for example, the vertex portion 141 can be a portion of the convex portion 140 where the tangent thereof is parallel to the main surface 152 of the substrate 108. Each of FIGS. 1 and 2 shows a section that passes through the vertex portion 141 of the convex portion 140 forming the surface 151 of the lens 117 and is parallel to the normal of the main surface 152 of the substrate 108.

In this embodiment, the vertex portion 141 forms a closed path in the orthogonal projection to the main surface 152 of the substrate 108. In the arrangement example shown in FIG. 1, the vertex portion 141 forms, for example, a circle. In the orthogonal projection to the main surface 152 of the substrate 108, the shape of the vertex portion 141 is not limited to be a circular shape, but may be, for example, a square shape, a rectangular shape, a hexagonal shape, or the like. On the other hand, in the comparative example shown in FIG. 2, the vertex portion 141 is one point and does not form a closed path.

If the lenses 117 respectively arranged in the light emitting elements 101 adjacent to each other are independently formed, an outer edge 145 of the lens 117 is an outermost peripheral portion of the lens 117. If the lenses 117 respectively arranged in the light emitting elements 101 adjacent to each other are continuously formed, the outer edge 145 of the lens is a portion where the tangent of the surface 151 of the lens 117 is parallel to the main surface 152 of the substrate 108 between the adjacent light emitting elements 101. For example, the outer edge 145 of the lens 117 may be a set of points where the distance from the main surface 152 of the substrate 108 is minimum in the surface 151 of the lens 117.

Around the outer edge 145 of the lens 117, a region that is convex opposite to the vertex portion 141 can exist. In the example shown in FIG. 1, a concave portion 144 is arranged around the outer edge 145 of the lens 117. The outer edge 145 of the lens 117 can be a portion of the concave portion 144 that is closest to the main surface 152 of the substrate 108. The boundary between the convex portion 140 and the concave portion 144 may be a set of inflection points where the surface 151 of the lens 117 changes from the convex shape to the concave shape. Alternatively, for example, the boundary between the convex portion 140 and the concave portion 144 may be a set of positions (points) where, between the vertex portion 141 of the convex portion 140 and the outer edge 145 of the lens 117, the angle (inclination angle θ) of the surface 151 of the lens 117 with respect to the main surface 152 of the substrate 108 is maximum. Here, from the vertex portion 141 of the convex portion 140 to the boundary between the convex portion 140 and the concave portion 144, the angle of the surface 151 of the lens 117 with respect to the main surface 152 of the substrate 108 may increase continuously or stepwise. Further, for example, from the outer edge 145 of the lens 117 to the boundary between the convex portion 140 and the concave portion 144, the angle of the surface 151 of the lens 117 with respect to the main surface 152 of the substrate 108 may increase continuously or stepwise. The concave portion 144 exists in the boundary portion with the adjacent light emitting element, and surrounds the vertex portion 141.

In the arrangement according to this embodiment shown in FIG. 1, the surface 151 of the lens 117 arranged in each light emitting element 101 includes a concave portion 143 surrounded by the convex portion 140 in the orthogonal projection to the main surface 152 of the substrate 108. A portion of the concave portion 143 that is closest to the main surface 152 of the substrate 108 is defined as a portion 142. The portion 142 can also be, for example, a portion of the concave portion 143 where the tangent thereof is parallel to the main surface 152 of the substrate 108. The boundary between the convex portion 140 and the concave portion 143 may be a set of inflection points where the surface 151 of the lens 117 changes from the convex shape to the concave shape. Alternatively, for example, the boundary between the convex portion 140 and the concave portion 143 may be a set of positions (points) where, between the vertex portion 141 of the convex portion 140 and the portion 142 of the concave portion 143, the angle (inclination angle θ) of the surface 151 of the lens 117 with respect to the main surface 152 of the substrate 108 is maximum. Here, from the vertex portion 141 of the convex portion 140 to the boundary between the convex portion 140 and the concave portion 143, the angle of the surface 151 of the lens 117 with respect to the main surface 152 of the substrate 108 may increase continuously or stepwise. Further, for example, from the portion 142 of the concave portion 143 to the boundary between the convex portion 140 and the concave portion 143, the angle of the surface 151 of the lens 117 with respect to the main surface 152 of the substrate 108 may increase continuously or stepwise.

In this manner, the surface 151 of the lens 117 according to this embodiment has a ring shape including the convex portion 140 and the concave portion 143 surrounded by the convex portion 140. On the other hand, in the surface 151 of the lens 117′ according to the comparative example shown in FIG. 2, a concave portion 144′ is arranged around the outer edge 145 of the lens 117 to surround the vertex portion 141, but a concave portion surrounded by the vertex portion 141 does not exist. In the arrangement according to this embodiment shown in FIG. 1, the concave portion 143 is arranged to overlap the center of the electrode 109. The portion 142 of the concave portion 143 that is closest to the main surface 152 of the substrate 108 may be arranged to overlap the center of the electrode 109. The center of the electrode 109 may be the position of the geometric centroid of the planar shape of the electrode 109 in the orthogonal projection to the main surface 152 of the substrate 108. Hence, it can also be considered that the concave portion 143 is arranged at the center of the light emitting element 101 in the orthogonal projection to the main surface 152 of the substrate 108.

The effects of this embodiment will be described below. Here, the inclination angle in the boundary between the convex portion 140 and the concave portion 143, more specifically, the angle at the position where the angle of the surface 151 of the lens 117 with respect to the main surface 152 of the substrate 108 is maximum between the vertex portion 141 of the convex portion 140 and the portion 142 of the concave portion 143 is defined as an inclination angle θ₁. Similarly, the inclination angle in the boundary between the convex portion 140 and the concave portion 144, more specifically, the angle at the position where the angle of the surface 151 of the lens 117 with respect to the main surface 152 of the substrate 108 is maximum between the vertex portion 141 of the convex portion 140 and the outer edge 145 of the lens 117 is defined as an inclination angle θ₂.

In this embodiment, the light emitting element 101 includes the lens 117 including the concave portion 143 surrounded by the vertex portion 141 (convex portion 140). With this arrangement, as compared to the lens 117′ of the comparative example shown in FIG. 2 where the vertex portion 141 is a point and the concave portion 143 is not provided, the inclination angles θ₁ and θ₂ can be decreased. More specifically, in the arrangements shown in FIGS. 1 and 2, assume that, for example, the convex portion 140 of the lens has a spherical (circular) shape and the radius of curvature in the sectional view is substantially the same between FIGS. 1 and 2. In this case, the inclination angle θ₁ in the boundary between the convex portion 140 and the concave portion 143 and the inclination angle θ₂ in the boundary between the convex portion 140 and the concave portion 144 are smaller than an inclination angle θ₂′ in the boundary between the convex portion 140 and the concave portion 144 in the comparative example. That is, a relationship of θ₁<θ₂′ and θ₂<θ₂′ holds. For light that is refracted at the convex portion 140 and extracted in the front direction, the smaller the angle between the tangent of the convex portion 140 and the main surface 152 of the substrate 108, the more light emitted from the light emitter 132 in a direction closer to the front direction can be extracted in the front direction. As will be described later, if the optical distance between the electrode 109 and the electrode 111 each functioning as a reflective layer is optimized with respect to the front direction, the radiation intensity from the light emitter 132 may be highest in the front direction, and decrease as the exit angle increases. In this case, as compared to the lens 117′ of the comparative example shown in FIG. 2, with the lens 117 of this embodiment shown in FIG. 1, light with the smaller exit angle, that is, light with relatively higher radiation intensity can be extracted in the front direction, so that the radiation intensity in the front direction can be improved. In addition, the color purity of light emitted from the light emitter 132 may decrease as the exit angle increases. Hence, if the lens 117 has the arrangement according this embodiment, light with higher color purity can be extracted.

Further, due to manufacturing reasons or the like, each of the concave portions 144 and 144′ formed around the outer edge 145 of the convex portion 140 may be formed as a downward convex curved surface (concave surface or concave lens). Since a downward convex curved surface does not have a light-harvesting property and diffuses light emitted from the light emitter 132, it may not be able to contribute to light extraction in the front direction. Accordingly, in the orthogonal projection to the main surface 152 of the substrate 108, if the occupancy ratio of the region (concave portion 144) as the downward convex curved surface increases, the light-extraction efficiency in the front direction can decrease. As described above, comparing to the lens 117 of this embodiment with the lens 117′ of the comparative example, θ₂<θ₂′ can be achieved. Thus, in the outer edge 145 of the lens 117, the curved surface intersects the adjacent lens 117 with a gentler angle. Accordingly, in the lens 117 of this embodiment, the width of the concave portion 144 in a sectional view can be decreased. That is, the occupancy ratio of the concave portion 144 can be decreased, thereby improving the front extraction efficiency. In the arrangement according to this embodiment shown in FIG. 1, a downward convex curved surface (concave surface or concave lens) may also be formed in the concave portion 143. However, the concave portion 143 exists as a point region surrounded by the vertex portion 141. Accordingly, the area occupied by the downward convex curved surface in the concave portion 143 can be decreased as compared to each of the concave portions 144 and 144′ surrounding the vertex portion 141. Hence, the influence on a decrease in front extraction efficiency in the concave portion 143 is small. In another viewpoint, since the inclination angles θ₁ and θ₂ can be decreased, the total occupancy area of the downward convex curved surfaces in the concave portion 143 and the concave portion 144 of the lens 117 of this embodiment can be set smaller than the occupancy area of the downward convex curved surface in the concave portion 144′ of the lens 117′ of the comparative example. Hence, the lens 117 of this embodiment can improve the front light-extraction efficiency.

As shown FIG. 1, the light emitter 132 and the convex portion 140 can be arranged such that the light emitter 132 and at least a part of the convex portion 140 overlap each other in the orthogonal projection to the main surface 152 of the substrate 108. Alternatively, for example, the light emitter 132 and the vertex portion 141 may be arranged such that the light emitter 132 and the vertex portion 141 of the convex portion 140 overlap each other in the orthogonal projection to the main surface 152 of the substrate 108. Since the tangent of the convex portion 140 in the vertex portion 141 is parallel to the main surface 152 of the substrate 108, by arranging the light emitter 132 and the vertex portion 141 so as to overlap each other, the light emitted from the light emitter 132 toward the vertex portion 141 in the front direction can be extracted intact in the front direction. Accordingly, as compared to a case where the light emitter 132 is arranged so as not to overlap the vertex portion 141, the front extraction efficiency can be improved.

As shown in FIG. 1, in the orthogonal projection to the main surface 152 of the substrate 108, each of the plurality of light emitting elements 101 may include a non-light emitting portion 133 surrounded by the light emitter 132. With this, the light emitter 132 and the concave portion 143 may be arranged such that the light emitter 132 and the concave portion 143 do not overlap each other in the orthogonal projection to the main surface 152 of the substrate 108. In other words, the non-light emitting portion 133 and the concave portion 143 may be arranged such that the non-light emitting portion 133 and the concave portion 143 overlap each other in the orthogonal projection to the main surface 152 of the substrate 108. Alternatively, the light emitter 132 and the concave portion 144 may be arranged such that the light emitter 132 and the concave portion 144 do not overlap each other in the orthogonal projection to the main surface 152 of the substrate 108. As described above, a downward convex curved surface may be formed in each of the concave portion 143 and the concave portion 144, and this may act to diffuse light from the light emitter 132. Therefore, even if the light emitter 132 is arranged to overlap the concave portion 143 and the concave portion 144, they may not contribute to light extraction in the front direction. Accordingly, by arranging the light emitter 132 so as not to overlap the concave portion 143 and the concave portion 144, the front light-extraction efficiency of light can be improved.

In the arrangement shown in FIG. 1, it has been described that the light emitter 132 does not overlap the concave portion 143 and the concave portion 144. However, the present invention is not limited to this. The light emitter 132 may be arranged to overlap the concave portion 143 and the concave portion 144 in the orthogonal projection to the main surface 152 of the substrate 108. With this arrangement, the viewing angle characteristics can be improved.

In the arrangement shown in FIG. 1, the shape of the outer edge of the light emitter 132 in the orthogonal projection to the main surface 152 of the substrate 108 can be a circular shape, and the shape of the outer edge of the non-light emitting portion 133 arranged to overlap the concave portion 143 can also be a circular shape. That is, it can also be said that the shape of the light emitter 132 is a ring shape in the orthogonal projection to the main surface 152 of the substrate 108. As described above, the concave portion 143 (portion 142) is arranged to overlap the center of the electrode 109. Therefore, in the orthogonal projection to the main surface 152 of the substrate 108, the length between the center of the light emitter 132 and the vertex portion 141 of the convex portion 140 is larger than the length between the center of the light emitter 132 and the portion 142 which is closest to the main surface 152 of the substrate 108 in the concave portion 143. The center of the light emitter 132 is, for example, the geometric centroid position of the ring-shaped light emitter 132 in the orthogonal projection to the main surface 152 of the substrate 108. Here, the planar shape of the light emitter 132 in this embodiment is not limited to the ring shape, and may be a circular shape or a polygonal shape such as a square, rectangular, or hexagonal shape, or may be a shape with the inside cut out into a circle, a polygon, or the like. Alternatively, a shape obtained by combining some of these figures may be used.

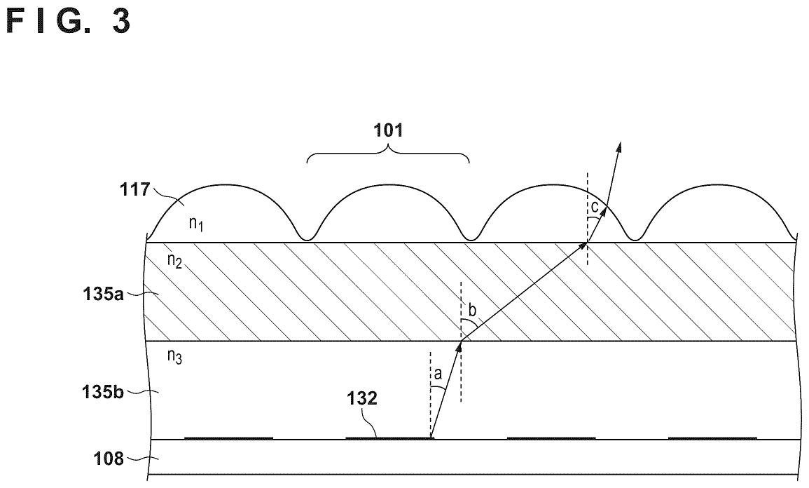

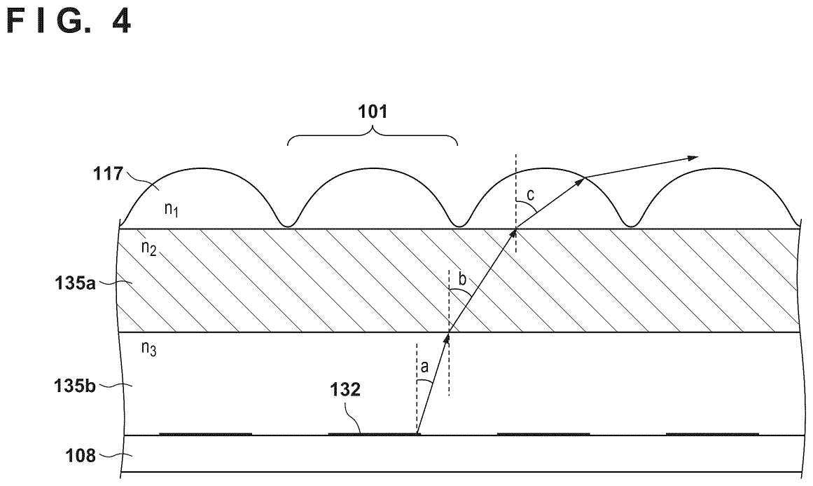

Next, assuming a case where medium layers each having a refractive index different from that of the lens 117 are provided between the light emitter 132 and the lens 117, the range of the refractive index of each medium layer will be described with reference to FIGS. 3 and 4. In the arrangement shown in FIG. 1, the medium layers include the protection layer 113, the planarizing layer 114, the color filter 115, and the planarizing layer 116 arranged between the light emitter 132 and the lens 117. Each of FIGS. 3 and 4 is a view showing an arrangement example in which medium layers 135a and 135b having different refractive indices are provided between the light emitter 132 and the lens 117. Let n₁ be the refractive index of the lens 117, n₂ be the refractive index of the medium layer 135a, and n₃ be the refractive index of the medium layer 135b. For example, the medium layer 135a may be the color filter 115. For example, the medium layer 135b may be the protection layer 113.

In the arrangement shown in FIG. 3, the refractive indices have a magnitude relationship of n₂<n₁<n₃. Considering the refraction of a light beam emitted in an oblique direction from the light emitter 132, angles a, b, c have a magnitude relationship of a<c<b in accordance with the magnitude relationship among the refractive indices. When c<b, the light beam is bent in a direction close to the front direction at the interface between the medium layer 135a and the lens 117. Therefore, as shown in FIG. 3, the light emitted from the light emitter 132 may exit in a direction close to the front direction from the lens 117 of the adjacent light emitting element 101. Thus, crosstalk may occur between the light emitting elements 101, thereby degrading image quality. Furthermore, since light having a large radiation angle from the light emitter 132 and low color purity may readily, visually be perceived, the color purity may deteriorate.

On the other hand, in the arrangement shown in FIG. 4, the refractive indices have a magnitude relationship of n₁<n₂<n₃. Therefore, the angles a, b, and c have a magnitude relationship of a<b<c, and the light emitted in the oblique direction from the light emitter 132 is refracted at the interface between the medium layer 135a and the lens 117 on the wide angle side, and is difficult to exit in the front direction. Therefore, it is possible to suppress the deterioration of the color purity.

As described above, when a layer with a refractive index lower than the refractive index n₁ of the lens 117 is not arranged between the light emitter 132 and the lens 117, it is possible to suppress crosstalk between the light emitting elements 101 and the deterioration of the color purity. That is, the refractive index of each of the medium layers 135a and 135b arranged between the light emitter 132 and the lens 117 may be equal to or higher than the refractive index of the lens 117. For example, in the arrangement shown in FIG. 4, the refractive index n₁ of the lens 117 and the refractive index n₂ of the medium layer 135a may satisfy a relationship of n₁<n₂. The refractive index n₃ of the medium layer 135b arranged between the medium layer 135a and the light emitter 132 may satisfy a relationship of n₁<n₃. Further, the refractive index n₃ of the medium layer 135b may satisfy a relationship of n₂<n₃. Three or more medium layers may be stacked. In that case as well, an arrangement is provided in which no layer having a refractive index lower than the refractive index n₁ of the lens 117 is arranged. For the medium layers adjacent to each other, the refractive index of the medium layer farther from the light emitter 132 may be equal to or higher than the refractive index of the medium layer closer to the light emitter 132. With this, it is possible to suppress crosstalk between the light emitting elements 101 and the deterioration of the color purity.

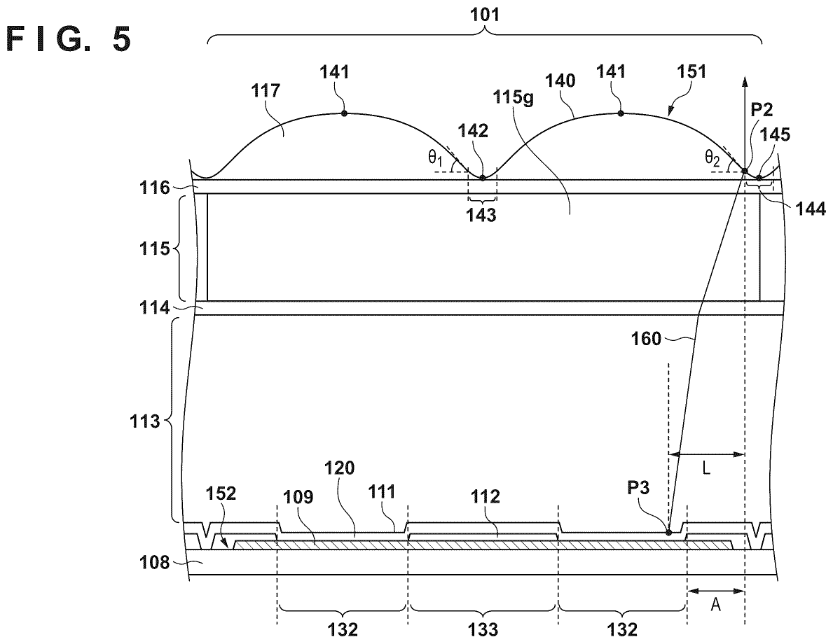

Next, with reference to FIG. 5, the positional relationship between the light emitter 132 and the lens 117 will be described. FIG. 5 is a schematic view for explaining an example of a light beam extracted in the front direction in a part of the section of the light emitting device 100 shown in FIG. 1. In the following description, a path will be considered in which light emitted from the light emitter 132 is refracted at the interface between the lens 117 having the refractive index n₁ and air having a refractive index of 1, and extracted in the front direction. Here, as shown in FIG. 5, consider the path of light 160 that is refracted at a position P2, where the angle of the surface 151 of the lens 117 with respect to the main surface 152 of the substrate 108 is maximum between the vertex portion 141 of the convex portion 140 and the outer edge 145 of the lens 117, and extracted in the front direction. In this case, the length that the light 160 travels from the position P2 to the surface of light emitter 132 in a direction parallel to the main surface 152 of substrate 108 is defined as a distance L. As shown in FIG. 5, if the light emitting element 101 is an organic light emitting element which includes the organic layer 120 including a light emitting layer, the surface of the light emitter 132 may be regarded as, for example, the surface of the electrode 111.

Letting θ₂ be the inclination angle of the surface 151 of the lens 117 at the position P2, according to Snell's law, an angle β₁ formed by the light 160 and the normal of the substrate 108 inside the lens 117 satisfies a relationship expressed by:

$${n}_{1} \cdot sin {α}_{1} = sin {θ}_{2} \qquad ( 1 )$$

$${β}_{1} = \vert {θ}_{2} - {α}_{1} \vert \qquad ( 2 )$$

Here, α₁ can also be regarded as the incident angle of the light 160 to the convex portion 140.

Letting H₁ be the thickness (the distance in a direction perpendicular to the main surface 152 of the substrate 108) of the lens 117 at the position P2, a distance L₁ that the light 160 travels in the lens 117 in a direction parallel to the main surface 152 of the substrate 108 is expressed by H₁·tan β₁.

Next, for the light 160 traveling to the position P2 with the angle β₁, the distance that the light 160 travels in the direction parallel to the main surface 152 of the substrate 108 in each layer forming the medium layers is considered. The angle in each layer can be obtained by considering the refraction at each interface. More specifically, when there are N layers including the layer of the lens 117, if the layer of the lens 117 is defined as the first layer, and n₁ represents the refractive index of the ith layer from the lens 117 toward the substrate 108, a light beam angle β₁ in the ith layer is obtained by:

$${n}_{i} \cdot sin {β}_{i} = {n}_{1} \cdot sin {β}_{1} \qquad ( 3 )$$

Thus, a distance Lᵢ that the light beam travels in the direction parallel to the main surface 152 of the substrate 108 in each layer is obtained using the above-described light beam angle βᵢ in each layer by:

$${L}_{i} = {H}_{i} \cdot tan {β}_{i} \qquad ( 4 )$$

The distance L that the light beam travels from the position P2 to the electrode 111 in the direction parallel to the main surface 152 of the substrate 108 is obtained by adding the distances Lᵢ that the light beam travels in the horizontal direction in the respective layers from i=1 to i=N. Accordingly, the distance L is expressed by:

$$L = {H}_{1} \cdot tan {β}_{1} + {H}_{2} \cdot tan {β}_{2} + … + {H}_{N} \cdot tan {β}_{N} \qquad ( 5 )$$

As shown in FIG. 5, in the orthogonal projection to the main surface 152 of the substrate 108, the length between the position P2 and the outer edge of the light emitter 132 closest to the position P2 is defined as a distance A. In the light emitter 132, a position P3 where light is emitted, that is to be transmitted through the position P2 and extracted in the direction perpendicular to the main surface 152 of the substrate 108, is located at the position of the distance L from the position P2 in the orthogonal projection to the main surface 152 of the substrate 108 as described above. In this case, a condition for the light 160 emitted from the light emitter 132 to be refracted at the position P2 and extracted in the front direction may satisfy a relationship of L>A. In other words, in the orthogonal projection to the main surface 152 of the substrate 108, the length (distance L) between the position P2 and the position P3 is larger than the length (distance A) between the position P2 and the outer edge of the light emitter 132. If the relationship of L>A is satisfied, the light 160 to be refracted at the position P2 and extracted in the front direction exists. As compared to a case where the relationship of L>A is not satisfied, the front extraction efficiency can be improved.

Here, referring back to FIG. 1, a more specific arrangement example of the light emitting device 100 will be described. As shown in FIG. 1, the light emitting device 100 can include the substrate 108, the electrodes 109, the organic layer 120, the electrode 111, the insulating layer 112, the protection layer 113, the planarizing layer 114, the color filters 115, the planarizing layer 116, and the lenses 117. In this embodiment, each of the electrode 109 and the electrode 111 functions as a reflective layer that reflects light as will be described later.

The electrode 109 is arranged on the main surface 152 of the substrate 108. The electrode 109 can also be referred to a lower electrode. The organic layer 120 includes a light emitting layer containing a light emitting material. A part of the organic layer 120 (light emitting layer) functions as the light emitter 132 described above. The organic layer 120 is arranged between the substrate 108 and the lens 117 to cover the electrodes 109. The electrode 111 is arranged on the organic layer 120. The electrode 111 can also be referred to as an upper electrode. The organic layer 120 (light emitting layer) emits light according to the potential difference between the electrode 109 and the electrode 111.

The insulating 112 is arranged between the adjacent electrodes 109 so as to insulate the adjacent electrodes 109 from each other. The insulating layer 112 may also be independently arranged on one electrode 109 so as to overlap the concave portion 143. The insulating layer 112 can also be called a bank. The insulating layer 112 is arranged, for example, on the electrode 109 and in the outer edge portion of the electrode 109. The exposed portion of each electrode 109, that is not covered with the insulating layer 112, is in contact with the organic layer 120. A portion of the organic layer 120, that is in contact with the electrode 109, can be the light emitter 132 described above. Therefore, as shown in FIG. 1, a plurality of light emitters 132 corresponding to the plurality of electrodes 109, respectively, can be arranged in the light emitting device 100.

The protection layer 113 is arranged on the electrode 111, and the planarizing layer 114 is arranged on the protection layer 113. The color filters 115 can be arranged on the planarizing layer 114 to respectively correspond to the plurality of electrodes 109. The planarizing layer 116 is arranged on the color filters 115. The lenses 117 are arranged on the planarizing layer 116. The lenses 117 are arranged to respectively correspond to the electrodes 109.

A material used for the substrate 108 is not particularly limited as long as the material can support the respective components of the light emitting device 100, such as the electrodes 109, the organic layer 120, and the electrode 111. For example, glass, plastic, or silicon may be used as the material of the substrate 108. A switching element such as a transistor, a wiring pattern, an interlayer insulating film, and the like may be provided on the main surface 152 of the substrate 108.

The electrodes 109 can be arranged to respectively correspond to the light emitting elements 101. The electrode 109 may be transparent or opaque to light emitted from the light emitter 132. If the electrode 109 is opaque, the material of the electrode 109 may be a metal material whose reflectance of the wavelength of light emitted from the light emitter 132 is 70% or more. For example, as the material of the electrode 109, a metal such as aluminum (Al) or silver (Ag), or an alloy obtained by adding silicon (Si), copper (Cu), nickel (Ni), neodymium (Nd), or the like to Al or Ag may be used. Alternatively, the electrode 109 may be a transparent electrode made of ITO, IZO, AZO, IGZO, or the like. In this case, the electrode 109 and a reflective layer opaque to light emitted from the light emitter 132 can be stacked. The electrode 109 may be a stacked electrode with a barrier electrode made of a metal such as titanium (Ti), tungsten (W), molybdenum (Mo), or gold (Au), or an alloy thereof, or a stacked electrode with a transparent oxide film electrode made of ITO, IZO, or the like as long as the required reflectance is obtained. To optimize an optical distance (to be described later), the electrode 109 may employ an arrangement in which an insulating film is provided between the reflective layer and a transparent conductive film.

The electrode 111 may be a semi-transmissive electrode having a characteristic (that is, a transflective property) of transmitting part of light that has reached the electrode 111 and reflecting the remaining part of the light. As the material of the electrode 111, for example, a transparent material such as a transparent conductive oxide may be used. As the material of the electrode 111, a semi-transmissive material of a single metal (Al, Ag, Au, or the like), an alkali metal (lithium (Lᵢ), cesium (Cs), or the like), an alkali earth metal (magnesium (Mg), calcium (Ca), barium (Ba), or the like), or an alloy material containing these metal materials may be used. If a semi-transmissive material is used as the material of the electrode 111, an alloy containing Mg or Ag as a main component may be used as a semi-transmissive material. The electrode 111 may have a stacked structure including a plurality of layers made of the above-described materials as long as it has an appropriate transmittance. In the arrangement shown in FIG. 1, the electrode 111 common to the plurality of light emitters 132 is provided. However, the present invention is not limited to this, and a plurality of electrodes 111 respectively corresponding to the plurality of light emitters 132 may be arranged.

One of the electrode 109 and the electrode 111 functions as an anode, and the other functions as a cathode. For example, the electrode 109 may function as an anode and the electrode 111 may function as a cathode. Alternatively, for example, the electrode 109 may function as a cathode and the electrode 111 may function as an anode.

The organic layer 120 can be formed by a known technique such as a deposition method or a spin coating method. The organic layer 120 may be formed from a plurality of layers. If the organic layer 120 is an organic compound layer, the organic layer 120 includes at least one of a hole injection layer, a hole transport layer, an electron blocking layer, a hole blocking layer, an electron transport layer, an electron injection layer, and the like in addition to the light emitting layer.

The light emitting layer emits light when holes injected from the anode and electrons injected from the cathode are recombined in the light emitting layer. The light emitting layer may include a single layer or a plurality of layers. If, for example, a light emitting layer containing a red light emitting material, a light emitting layer containing a green light emitting material, and a light emitting layer containing a blue light emitting material are combined, light beams (red light, green light, and blue light) from the respective light emitting layers can be mixed to obtain white light. Two kinds of light emitting layers whose light emission colors have a complimentary color relationship (for example, a light emitting layer containing a blue light emitting material and a light emitting layer containing a yellow light emitting material) may be combined. In the light emitting device 100 shown in FIG. 1, each light emitter 132 emits white light and the light is colored in the color filter 115. However, the present invention is not limited to this. A material contained in a light emitting layer and the arrangement of the light emitting layer may be different for each light emitter 132 so that the light emitting layer emits light of a different color for each light emitter 132. In this case, the light emitting layer may be patterned for each light emitter 132.

The light emitting device 100 may have a so-called tandem structure in which the organic layer 120 includes a plurality of light emitting layers and a charge generating layer arranged between the plurality of light emitting layers. By having the tandem structure, the plurality of light emitting layers emit light at the same time, thereby improving light emission efficiency.

Here, a description will be given assuming that the electrode 109 reflects light emitted from the light emitter 132. In this case, to optimize the optical distance between the first reflective surface as the surface of the electrode 109 and the light emitting region (light emission position) of the organic layer 120 including the light emitting layer, equation (6) below is satisfied. In equation (6), Lᵣ represents an optical path length (optical distance) from the first reflective surface as the surface of the electrode 109 to the light emission position of the organic layer 120, Φᵣ represents a phase shift when light of a wavelength k is reflected by the first reflective surface, and m represents an integer of 0 or more. The film thickness between the electrode 109 and the organic layer 120, the film thickness of each layer of the organic layer 120, and the like may be designed so as to satisfy equation (6).

$${L}_{r} = ( 2 \times m - ( {Φ}_{r} / π ) ) \times ( λ / 4 ) \qquad ( 6 )$$

Furthermore, if Φₛ represents a phase shift when light of the wavelength λ is reflected by the second reflective surface, and m₂ is an integer of 0 or more, an optical distance Lₛ from the light emission position to the second reflective surface as the lower surface of the electrode 111 needs to satisfy equation (7) below.

$${L}_{s} = ( 2 \times {m}_{2} - ( {Φ}_{s} / π ) ) \times ( λ / 4 ) \qquad ( 7 )$$

Therefore, a whole layer interference L needs to satisfy equation (8) below. In equation (8), Φ represents a sum of the phase shift Φᵣ and the phase shift Φₛ, and m₃ is an integer of 0 or more.

$$L = {L}_{r} + {L}_{s} = ( 2 \times {m}_{3} - Φ / π ) \times ( λ / 4 ) \qquad ( 8 )$$

In this example, in equations (6) to (8) above, an allowable range is about λ/8 or about 20 nm. Since it may be difficult to specify the light emission position in the organic layer 120, the interface on the first reflective surface side or the second reflective surface side of the light emitting layer of the organic layer 120 is used instead of the light emission position in the above example. In consideration of the above-described allowable range, even if the interface is used instead, an effect of intensifying light can be obtained.

The protection layer 113, the planarizing layer 114, the color filters 115, and the planarizing layer 116 form the above-described medium layer 135. The protection layer 113 is a dielectric layer. The protection layer 113 has a transmissive property that allows light emitted from the light emitter 132 to pass therethrough. Furthermore, the protection layer 113 may contain an inorganic material having a low permeability for oxygen and water from the outside of the light emitting device 100. For example, the protection layer 113 may be formed using an inorganic material such as silicon nitride (SiN), silicon oxynitride (SiON), silicon oxide (SiOₓ), aluminum oxide (Al₂O₃), or titanium oxide (TiO₂). In terms of the protection performance, the protection layer 113 may be made of an inorganic material such as SiN, SiON, or Al₂O₃. A chemical vapor deposition (CVD) method, an atomic layer deposition (ALD) method, a sputtering method, or the like can be used to form the protection layer 113.

The protection layer 113 can have a single-layer structure using the above-described material or a stacked structure using the above-described materials in combination as long as the protection layer 113 has sufficient water block performance. For example, the protection layer 113 may have a stacked structure of a layer of SiN formed using the CVD method and another layer (for example, Al₂O₃) having a high density formed using the ALD method. Furthermore, the protection layer 113 may include an organic layer as long as it has water block performance. For example, polyacrylate, polyamide, polyester, epoxy, or the like can be used for the organic layer. In addition, in the arrangement shown in FIG. 1, the protection layer 113 common to the plurality of light emitters 132 is provided but a plurality of protection layers 113 respectively corresponding to the plurality of light emitters 132 may be arranged.

The lens 117 can be formed by an exposure process and a developing process. More specifically, a material film (for example, a photoresist film) of the lens 117 is formed, and the photoresist film is exposed and developed using a mask including a continuous change in gradation. As the mask used to form the lens 117, a gray mask can be used. An area gradation mask that allows light irradiation with a continuous change in gradation on the imaging plane by changing the density distribution of dots of a light shielding film with a resolution equal to or lower than the resolution of an exposure device can be used as the mask used to form the lens 117. The lens shape can be adjusted by etching back the lens 117 formed by the exposure process and the developing process. As describe above, the surface 151 of the lens 117 includes the convex portion 140 having the convex shape in a direction away from the main surface 152 of the substrate 108. Apart of the convex portion 140 may be a part of a spherical surface (circle), or may be aspherical.

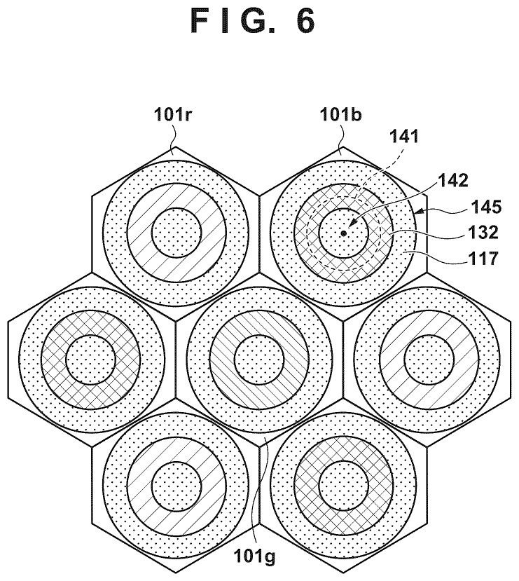

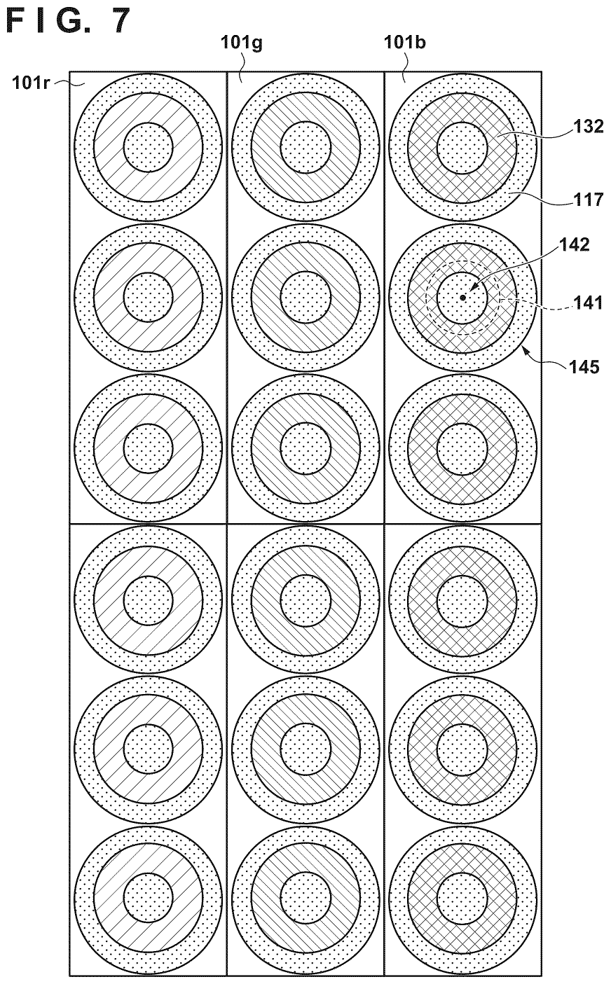

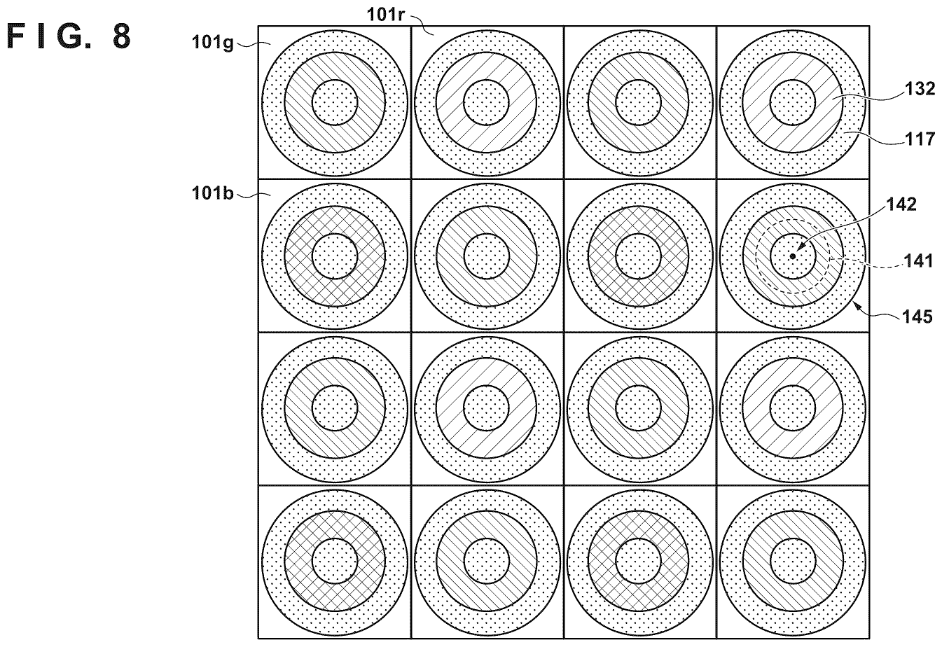

The light emitting element 101 is formed by a combination of the light emitter 132, the convex portion 140 and the concave portion 143 of the lens 117, and the like. If a plurality of light emitting elements 101 are provided, the planar arrangement (the arrangement when viewed from the normal direction of the main surface 152 of the substrate 108) of the plurality of light emitting elements 101 may be any of a stripe arrangement, a square arrangement, a delta arrangement, a pentile arrangement, and a Bayer arrangement. FIGS. 6 to 8 are plan views when viewing the light emitting device 100 from the side of the lens 117, and each show an example of the planar arrangement of the plurality of light emitting elements 101. FIG. 6 shows an example of the delta arrangement. FIG. 7 shows an example of the stripe arrangement. FIG. 8 shows an example of the Bayer arrangement. In this example, consider a case where the light emitting device 100 is used as a display panel, and one pixel (main pixel) includes a plurality of sub-pixels having different corresponding color components (for example, a sub-pixel that performs red display, a sub-pixel that performs green display, and a sub-pixel that perform blue display). In this case, as shown in FIG. 7, the plurality of light emitting elements 101 may be arranged in one sub-pixel. The size and shape of the convex portion 140 of the lens 117 may appropriately be set in accordance with the planar arrangement of the plurality of light emitting elements 101. For example, if the delta arrangement is adopted, an area occupied by the convex portion 140 of the surface 151 of the lens 117 with respect to the sub-pixel can be set large, thereby improving light-extraction efficiency.

In the arrangements shown in FIGS. 6 to 8, the planar shape (the shape when viewed from the normal direction of the main surface 152 of the substrate 108) of the light emitter 132 is a ring shape, but the planar shape of the light emitter 132 is not limited to this. The planar shape of the light emitter 132 may be, for example, a polygonal shape such as a rectangular or hexagonal shape, or may a shape with the inside cut out into a circle, a polygon, or the like.

The lenses 117 may be formed so that the outer edge 145 of the convex portion 140 forming the surface 151 of each lens 117 has a thickness (parts of the adjacent lenses 117 overlap each other). In this case, as described above, the outer edge 145 of the lens 117 can be a set of portions where the tangent of the surface 151 of the lens 117 is parallel (the inclination angle is 0°) to the main surface 152 of the substrate 108 between the adjacent lenses 117.

As described above, an arrangement in which the lenses 117 transmit light beams of different colors may be adopted. With this, the light emitting device 100 can perform full-color display. As a method of implementing full-color display, a method of using the color filters 115 and the light emitting layer that emits white light may be adopted. Since the plurality of light emitters 132 can share the light emitting layer, a manufacturing process of the light emitting layer is easier than in a case where the light emitting layer is patterned to emit light of a different color for each light emitter 132. However, the light emitting layer may be patterned so that the plurality of light emitters 132 emit light beams of different colors. Furthermore, the above-described optical path length L (the optical path length Lᵣ or Lₛ) between the first reflective layer and the second reflective layer may be different for each of the light emitters 132 that emit light beams of different colors.

As described above, the center of the concave portion 143 of the convex portion 140 can be arranged at the center of the electrode 109 in the orthogonal projection to the main surface of the substrate. Further, the vertex portion 141 forms a circle, and the center of the circle can overlap the center of the electrode 109 and the light emitter 132 in the orthogonal projection to the main surface 152 of the substrate 108. On the other hand, in order to improve the light-extraction efficiency in a specific direction, the center of the light emitter 132 and the center of the concave portion 143 may be arranged to shift from each other. In the light emitting element 101 arranged in the light emitting device 100, the center of the light emitter 132 and the center of the concave portion 143 may be shifted in the same direction in the entire region. Alternatively, the center of the light emitter 132 and the center of the concave portion 143 may be arranged to overlap each other near the center of an element region of the light emitting device 100 where the plurality of light emitting elements 101 are arranged, and the shift between the center of the light emitter 132 and the center of the concave portion 143 may be increased toward the outside of the element region. In this case, the center of the concave portion 143 may be shifted from the center of the light emitter 132 in a direction toward the outer peripheral portion of the light emitting device 100.

In this embodiment, the color filters 115 are provided on the planarizing layer 114. However, the present invention is not limited to this, and the color filters 115 may be provided on the protection layer 113. For example, the color filters 115 and the protection layer 113 may be continuous without arranging the planarizing layer 114. Alternatively, for example, the color filters 115 and the protection layer 113 may be integrated. The color filters 115 may be formed on a support substrate different from the substrate 108 and this substrate may be bonded so as to oppose the protection layer 113, thereby forming the color filters 115 of the light emitting device 100.

The planarizing layer 114 is provided to planarize unevenness of the surface of the protection layer 113. By arranging the planarizing layer 114, the color filters 115 can be formed to be accurately aligned with the respective light emitters 132 using a photolithography process. As described above, by integrating the color filters 115 and the protection layer 113 without arranging the planarizing layer 114, the color filters 115 can be formed to be accurately aligned with the respective light emitters 132 using a photolithography process.

In the arrangement shown in FIG. 1, color filters 115r, 115g, and 115b may be color filters configured to transmit light beams of different colors. For example, the color filter 115r may transmit red light, the color filter 115g may transmit green light, and the color filter 115b may transmit blue light. Some or all of the plurality of color filters 115 may not be arranged to configure the light emitting device 100 as a device that emits a single light emission color. Alternatively, if the light emitting layer of the organic layer 120 is formed for each light emitting element 101 to differentiate the colors of the light beams emitted from the light emitters 132, the light emitting device 100 may be a device that can perform full-color display.

Furthermore, in this embodiment, the lenses 117 are provided on the planarizing layer 116. The planarizing layer 116 is provided to planarize unevenness of the surfaces of the color filters 115. However, the lenses 117 may be provided on the color filters 115. In this case, the planarizing layer 116 need not be arranged. Alternatively, the lenses 117 and the color filters 115 may be integrated.

Furthermore, the lenses 117 may be provided on the protection layer 113 without arranging the color filters 115 and the planarizing layers 114 and 116. For example, the lenses 117 and the protection layer 113 may be integrated. If the lenses 117 and the protection layer 113 are integrated, the distance from the lens 117 to the light emitter 132 can be shortened, as compared with a case where the lenses 117 are formed on another substrate and this substrate is bonded so as to oppose the protection layer 113. As a result, the solid angle of light entering the lens 117 from the light emitter 132 can be increased, thereby improving light-extraction efficiency. By integrating the lenses 117 and the protection layer 113, the convex portion 140 of each lens 117 can be accurately aligned with the corresponding light emitter 132. For example, by integrating the color filters 115, the lenses 117, and the protection layer 113, the light emitters 132, the color filters 115, and the lenses 117 can accurately be aligned, respectively.

The stacking order of the color filters 115 and the lenses 117 can appropriately be selected. In the arrangement shown in FIG. 1, the color filters 115 are provided on the side of the light emitters 132 with respect to the lenses 117. In this arrangement, light emitted from the light emitter 132 passes through the color filter 115 before entering the lens 117. Thus, light (light having a large exit angle from the light emitter) that causes deterioration of the color purity passes through the color filter 115 over a relatively long distance. Therefore, it is possible to suppress the deterioration of the color purity when observing the light emitting device 100 from the oblique direction.

The light emitting device 100 may be manufactured by forming the color filters 115 and the lenses 117 on a support substrate different from the substrate 108 and bonding the substrate so as to oppose the substrate 108 including the light emitters 132. When the color filters 115 and the lenses 117 are formed separately from the organic layer 120 (light emitting layer), the degree of freedom of a processing method (for example, a temperature and the like) when forming the color filters 115 and the lenses 117 improves, thereby making it possible to increase the degree of freedom of the design of the color filters 115 and the lenses 117. The color filters 115 and the lenses 117 may be continuously formed on one support substrate, or the color filters 115 and the lenses 117 may be formed on different support substrates. For example, the lenses 117 and the color filters 115 can be coupled to the substrate 108 using a coupling member such as an adhesive. The coupling member may be arranged on the planarizing layer 114, or may be arranged on the protection layer 113 in a case where the planarizing layer 114 is not arranged.

The lenses 117 may be formed on a support substrate different from the substrate 108 and the substrate may be bonded to oppose the substrate 108 including the light emitters 132. In this case, the lenses 117 may be fixed to the substrate 108 by a coupling member such as an adhesive in the end portion of the light emitting device 100 so as to provide a space between the lenses 117 and the protection layer 113 (or the color filters 115). In this case, the space may be filled with a resin. The refractive index of the resin may be lower than the refractive index n₁ of the lens 117.

Examples of the light emitting device 100 will be described below while comparing with the light emitting device 100′ of the comparative example. In the examples described below, the light emitting device 100 of Example 1 has an arrangement similar to that of the light emitting device 100′ of the comparative example except for the shapes of the light emitter 132 and the lenses 117 and 117′.

### Example 1

First, aluminum was formed on a substrate 108, thereby forming a plurality of electrodes 109 respectively corresponding to light emitting elements 101. Next, silicon oxide of a film thickness of 65 nm was formed as a material film of an insulating layer 112 to cover each of the plurality of electrodes 109. In the formed material film, an opening portion was formed in the central portion of each of the plurality of electrodes 109 to expose the electrode 109, thereby forming the insulating layer 112. In a light emitting device 100 of this example, the opening portion that exposes the electrode 109 had a circular outer shape with a radius of 2.4 μm, and the insulating layer 112 having a circular shape with a radius of 1.0 μm was left inside. On the other hand, in the comparative example, to make the area of the opening portion substantially equivalent to that of the light emitting device 100 of this example, the shape of the opening portion was a circular shape having a radium of 2.2 μm. As described above, the opening portion formed in the insulating layer 112 finally corresponds to a light emitter 132. That is, in the orthogonal projection to a main surface 152 of the substrate 108, the size and shape of the opening portion can match the size and shape of the light emitter 132.

After the insulating layer 112 was formed, an organic layer 120 was formed on the plurality of electrodes 109 and the insulating layer 112. More specifically, a hole injection layer was formed to a thickness of 3 nm by compound 1 (to be described below). On the hole injection layer, a hole transport layer was formed to a thickness of 15 nm by compound 2. On the hole transport layer, an electron blocking layer was formed to a thickness of 10 nm by compound 3. Next, a first light emitting layer was formed to a thickness of 10 nm such that compound 4 serving as a host material was contained in a weight ratio of 97% and compound 5 serving as a light emitting dopant was contained in a weight ratio of 3%. Next, a second light emitting layer was formed to a thickness of 10 nm such that compound 4 serving as a host material was contained in a weight ratio of 98% and compounds 6 and 7 serving as light emitting dopants were respectively contained in a weight ratio of 1%. Next, on the second light emitting layer, an electron transport layer was formed to a thickness of 110 nm by compound 8. Next, on the electron transport layer, an electron injection layer was formed to a thickness of 1 nm by lithium fluoride.

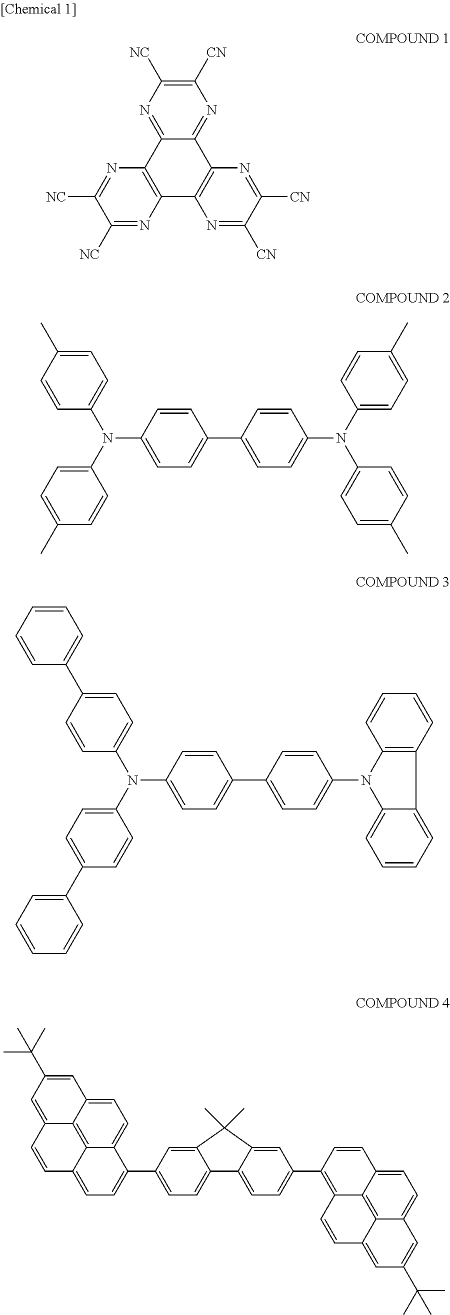

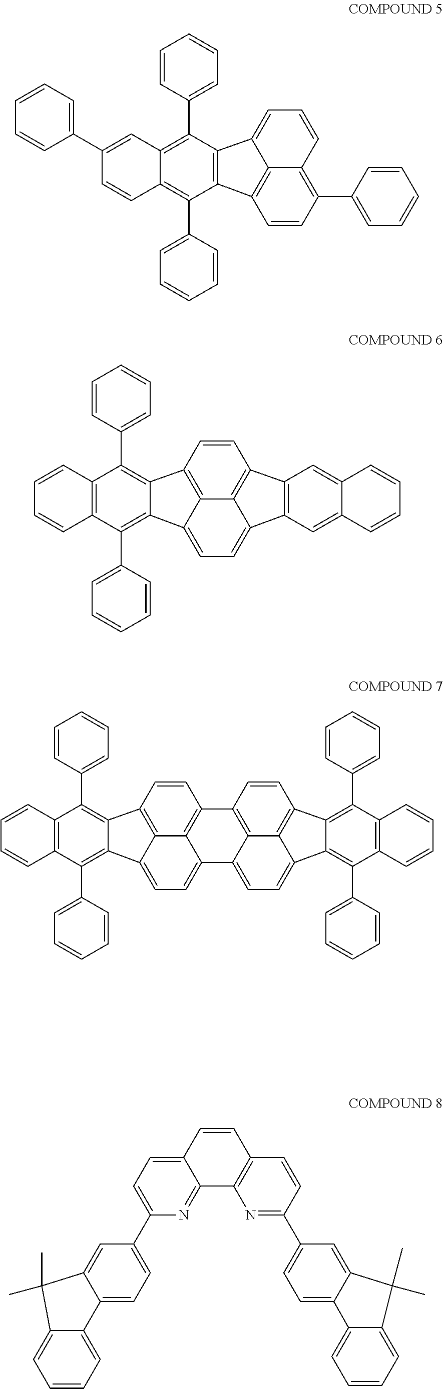

After the organic layer 120 was formed, an Mg/Ag alloy was formed to a thickness of 10 nm as the electrode 111 on the organic layer 120. The ratio of Mg and Ag was 1:1. After that, as a protective layer 113, SiN with a refractive index of 1.97 was formed to a thickness of 2.0 μm on the electrode 111 by the CVD method. Next, a planarizing layer 114 with a refractive index of 1.55 was formed to a thickness of 0.2 μm on the protection layer 113 by the spin coating method.

Next, color filters 115 with a refractive index of 1.65 were formed to a thickness of 1.6 μm on the planarizing layer 114. A color filter 115r was a color filter configured to transmit red light, a color filter 115g was a color filter configured to transmit green light, and a color filter 115b was a color filter configured to transmit blue light. After the color filters 115 were formed, a planarizing layer 116 with a refractive index of 1.55 was formed to a thickness of 0.2 μm on the color filters 115 by the spin coating method.

Next, a lens 117 with a refractive index of 1.52 was formed by an exposure process and a developing process on the planarizing layer 116. A convex portion 140 of the lens 117 had a sectional shape which is a part of an approximately spherical surface (circle). In the light emitting device 100 in this example, a distance h as a difference in height between a vertex portion 141 of the convex portion 140 and a portion 142 of a concave portion 143 in the normal direction of the main surface 152 of the substrate 108 was 0.9 μm. Furthermore, in the orthogonal projection to the main surface 152 of the substrate 108, a distance r₁ between the vertex portion 141 of the convex portion 140 and the portion 142 of the concave portion 143 and a distance r₂ between the vertex portion 141 of the convex portion 140 and an outer edge 145 of the lens 117 were both 1.65 μm. Accordingly, in the orthogonal projection to the main surface 152 of the substrate 108, the vertex portion 141 draws a circle with a radius of 1.65 km. In this example, the distance (pixel pitch P) between the centers of the adjacent light emitting elements 101 is 6.6 μm, so that a relationship of r₁=0.25P holds. At this time, an inclination angle θ₁ and an inclination angle θ₂ at positions where the angle of a surface 151 of the lens 117 with respect to the main surface 152 of the substrate 108 is maximum near the concave portion 143 and near the concave portion 144, respectively, were both about 55°.

In a light emitting device 100′ of the comparative example, a difference in height between the vertex portion 141 of the convex portion 140 and an outer edge 145 in the normal direction of the main surface 152 of the substrate 108 (the height of a lens 117′) was 2.5 μm. Furthermore, in the orthogonal projection to the main surface 152 of the substrate 108, the distance between the vertex portion 141 of the convex portion 140 of the lens 117′ and the outer edge 145 of the lens 117′ (the radius of the bottom surface of the lens 117′) was 3.3 km. At this time, an inclination angle θ₂′ at a position where the angle of the surface 151 of the lens 117′ with respect to the main surface 152 of the substrate 108 was maximum was about 70°.

Comparing the light emitting device 100 of this example with the light emitting device 100′ of the comparative example, the sizes of the light emitters 132 are approximately equal, but the maximum inclination angles θ₁ and θ₂ with respect to the main surface 152 of the substrate 108 near the concave portion 143 and the concave portion 144, respectively, in the light emitting device 100 of this example was smaller than the inclination angle θ₂′ in the light emitting device 100′ of the comparative example. As described above, in the light emitting device 100 of this example, since the maximum inclination angle of the surface 151 of the lens 117 can be made small, light with a small exit angle from the light emitter 132 can be extracted in the front direction. Furthermore, in the orthogonal projection to the main surface 152 of the substrate 108, the area occupied by the concave portions 143 and 144 in the light emitting element 101 in the light emitting device 100 of this example can be smaller than the area occupied by the concave portion 144′ in the light emitting element 101 of the light emitting device 100′ of the comparative example. As a result, the light emitting device 100 of this example was able to increase the front extraction light amount and extract light with high color purity.

### Example 2

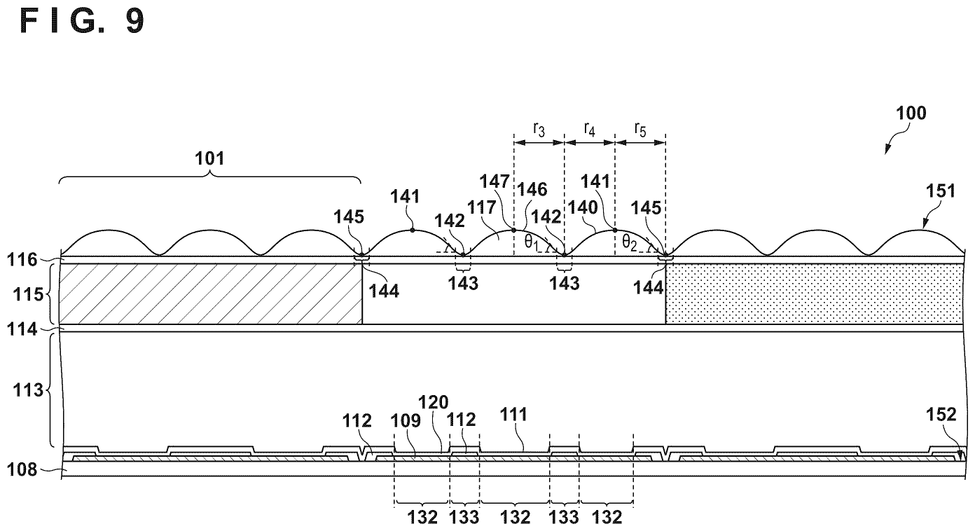

A light emitting device 100 according to Example 2 will be described next with reference to FIG. 9. FIG. 9 is a schematic sectional view of the light emitting device 100 according to this example.

In this example, two independent light emitters 132 were arranged as the light emitter 132 in one light emitting element 101. More specifically, one light emitter 132 had a ring shape with an outer diameter of 2.6 μm and an inner diameter of 1.6 μm. The other light emitter 132 had a circle shape with a radius of 0.8 μm. In that case, the centroids of the two light emitters 132 were matched.

Further, the shape of a lens 117 in this example was different from the lens 117 in Example 1. As shown in FIG. 9, in addition of a convex portion 140 surrounding a concave portion 143, the lens 117 in this example further included a convex portion 146 surrounded by the concave portion 143 and protruding in a direction away from a main surface 152 of a substrate 108. The convex portion 146 had a vertex 147 where the tangent thereof was parallel to the main surface 152 of the substrate 108.

Here, in the orthogonal projection to the main surface 152 of the substrate 108, a vertex portion 141 of the convex portion 140 had a circular shape as in Example 1, and surrounded the concave portion 143. In the orthogonal projection to the main surface 152 of the substrate 108, the concave portion 143 also had a circular shape. On the other hand, in the orthogonal projection to the main surface 152 of the substrate 108, the vertex 147 of the convex portion 146 is a “point”.

In this example, a distance has a difference in height between the vertex portion 141 of the convex portion 140 and a portion 142 of the concave portion 143 in the normal direction of the main surface 152 of the substrate 108 was 0.4 μm. Furthermore, in the orthogonal projection to the main surface 152 of the substrate 108, each of a distance r₃ between the vertex 147 of the convex portion 146 and the portion 142 of the concave portion 143, a distance r₄ between the vertex portion 141 of the convex portion 140 and the portion 142 of the concave portion 143, and a distance r₅ between the vertex portion 141 of the convex portion 140 and an outer edge 145 of the lens 117 was 1.1 μm. At this time, an inclination angle θ₁ and an inclination angle θ₂ at positions where the angle of a surface 151 of the lens 117 with respect to the main surface 152 of the substrate 108 is maximum near the concave portion 143 and near the concave portion 144, respectively, were both about 38°. The remaining arrangement is similar to that of the light emitting device 100 of Example 1.

As in this example, even with the concave portion 143 having a circular shape in the orthogonal projection to the main surface 152 of the substrate 108, it was possible to make the maximum inclination angles θ₁ and θ₂ of the surface 151 of the lens 117 with respect to the main surface 152 of the substrate 108 smaller than in the light emitting device 100′ of the comparative example. As a result, it was possible to increase the front extraction light amount and extract light with high color purity.

In this example, a case has been described in which the concave portion 143 is a single circle in the orthogonal projection to the main surface 152 of the substrate 108, but the present invention is not limited to this. Even with an arrangement in which the concave portion 143 is formed by a plurality of concentric circles or a single or plurality of polygons, the maximum inclination angle of the surface 151 of the lens 117 with respect to the main surface 152 of the substrate 108 can be decreased. That is, the above-described effect of the present disclosure can be obtained.

### Example 3

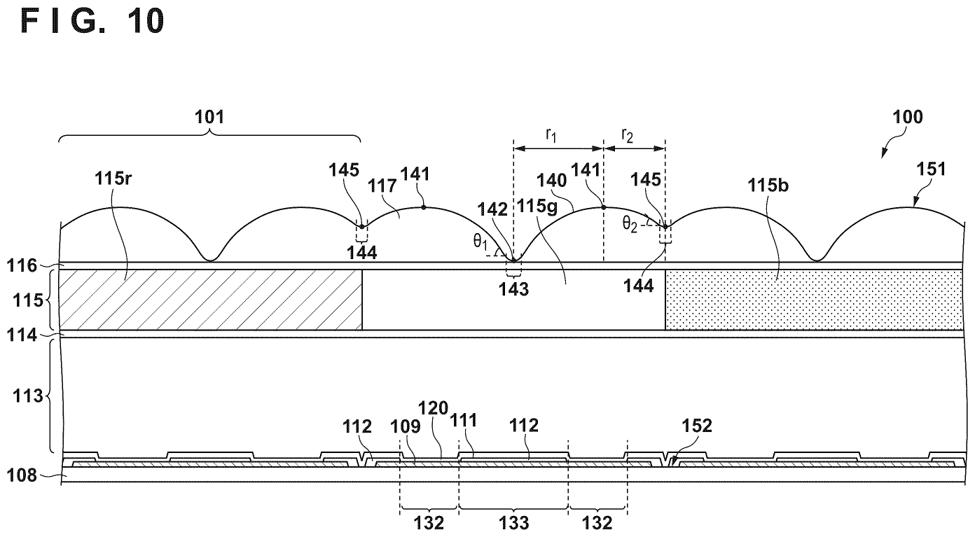

Next, a light emitting device 100 according to Example 3 will be described with reference to FIG. 10. FIG. 10 is a schematic sectional view of the light emitting device 100 according to this example.

In this example, a light emitter 132 had a circular outer shape with a radius of 2.75 μm, an insulating layer 112 having a circular shape with a radius of 1.65 μm was left inside.

Furthermore, the shape of a lens 117 in this example was different from the lens 117 in each of Examples 1 and 2. For the lens 117 of this example, in the orthogonal projection to a main surface 152 of a substrate 108, a distance r₁ between a vertex portion 141 of a convex portion 140 and a portion 142 of a concave portion 143 was 2.2 μm, and a distance r₂ between the vertex portion 141 of the convex portion 140 and an outer edge 145 of the lens 117 was 1.1 μm. Further, a distance h as a difference in height between the vertex portion 141 of the convex portion 140 and the portion 142 of the concave portion 143 in the normal direction of the main surface 152 of the substrate 108 was 1.5 μm. At this time, an inclination angle θ₁ at a position where the angle of the surface 151 of the lens 117 with respect to the main surface 152 of the substrate 108 was maximum near the concave portion 143 was about 65°. In addition, an inclination angle θ₂ at a position where the angle of the surface 151 of the lens 117 with respect to the main surface 152 of the substrate 108 was maximum near the concave portion 144 was about 27°. That is, the maximum angle (inclination angle θ₂) of the surface 151 of the lens 117 with respect to the main surface 152 of the substrate 108 between the vertex portion 141 of the convex portion 140 and the outer edge 145 of the lens 117 was smaller than the maximum angle (inclination angle θ₁) of the surface 151 of the lens 117 with respect to the main surface 152 of the substrate 108 between the vertex portion 141 of the convex portion 140 and the portion 142 of the concave portion 143 closest to the main surface 152 of the substrate 108. Furthermore, in the normal direction of the main surface 152 of the substrate 108, the length between the outer edge 145 of the lens 117 and the main surface 152 of the substrate 108 is larger than the length between the portion 142 of the concave portion 143 and the main surface 152 of the substrate 108. The remaining arrangement is similar to that of the light emitting device 100 in Example 1.

In the orthogonal projection to the main surface 152 of the substrate 108, if the widths of regions as downward convex curved surfaces are the same, the region near a concave portion 144 as the peripheral portion of one light emitting element 101 has a large area than the region near the concave portion 143 at the center of the light emitting element 101. Accordingly, the region near the concave portion 144 can have a greater influence on the light-extraction efficiency. Therefore, as in this example, the maximum inclination angle θ₂ of the surface 151 of the lens 117 with respect to the main surface 152 of the substrate 108 between the vertex portion 141 and the outer edge 145 is set smaller than the maximum inclination angle θ₁ of the main surface 151 of the lens between the vertex portion 141 and the portion 142. With this, the front extraction light amount increases.

In this example, a relationship of θ₁>θ₂ was implemented by satisfying a relationship of r₁>r₂. However, the present invention is not limited to this. For example, the relationship of θ₁>θ₂ may be implemented by changing the curvature of the surface 151 of the lens 117 between the vertex portion 141 of the convex portion 140 and the portion 142 of the concave portion 143 from that between the vertex portion 141 of the convex portion 140 and the outer edge 145 of the lens 117.

Here, application examples in which the light emitting device 100 according to this embodiment is applied to an image forming device, a display device, a photoelectric conversion device, an electronic apparatus, an illumination device, a moving body, and a wearable device will be described with reference to FIGS. 11A to 18B.

FIGS. 11A to 11C are schematic views showing an example of an image forming device using the light emitting device 100 according to this embodiment. An image forming device 926 shown in FIG. 11A includes a photosensitive member 927, an exposure light source 928, a developing unit 931, a charging unit 930, a transfer device 932, a conveyance unit 933 (a conveyance roller in the arrangement shown in FIG. 11A), and a fixing device 935.

Light 929 is emitted from the exposure light source 928, and an electrostatic latent image is formed on the surface of the photosensitive member 927. The light emitting device 100 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 11B and 11C is a schematic view showing a form in which a plurality of light emitting units 936 are arranged in the exposure light source 928 along the longitudinal direction of a long substrate. The light emitting device 100 can be applied to each of the light emitting units 936. That is, the plurality of pixels are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 11B shows a form in which the light emitting units 936 are arranged along the long-axis direction of the photosensitive member 927. FIG. 11C shows a form, which is a modification of the arrangement of the light emitting units 936 shown in FIG. 11B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 11C can be referred to as, for example, an arrangement in a grid pattern, an arrangement in a staggered pattern, or an arrangement in a checkered pattern.

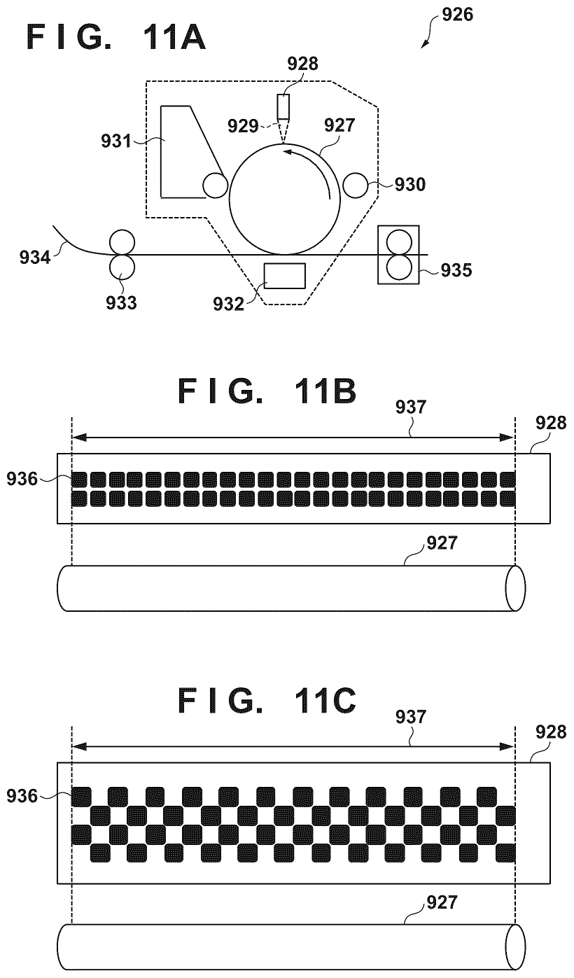

FIG. 12 is a schematic view showing an example of the display device using the light emitting device 100 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 100 can be applied to the display panel 1005. The pixels arranged in the light emitting device 100 functioning as the display panel 1005 operate in a state in which they are connected to the active elements such as transistors arranged on the circuit board 1007.

The display device 1000 shown in FIG. 12 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

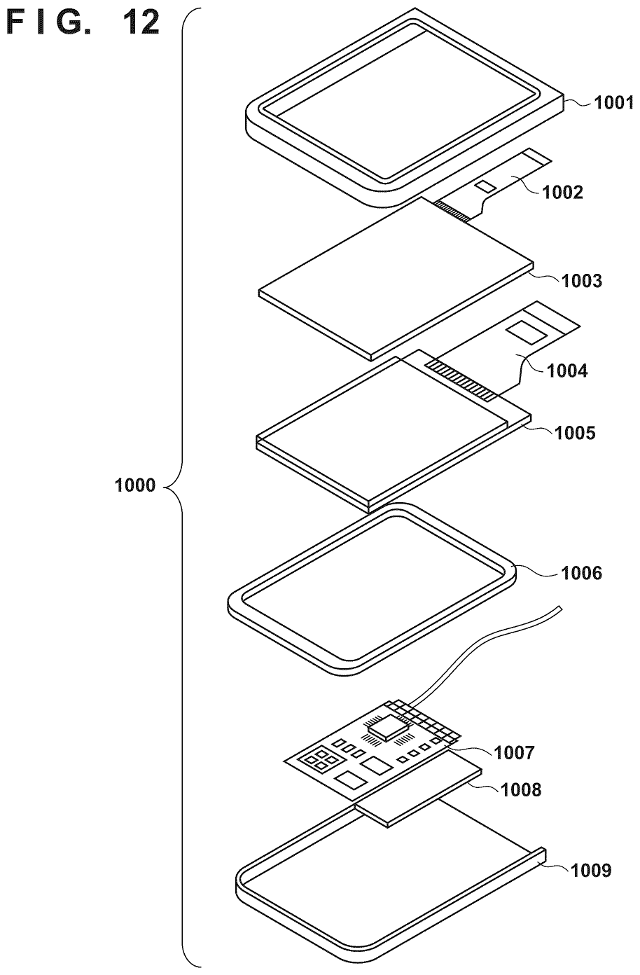

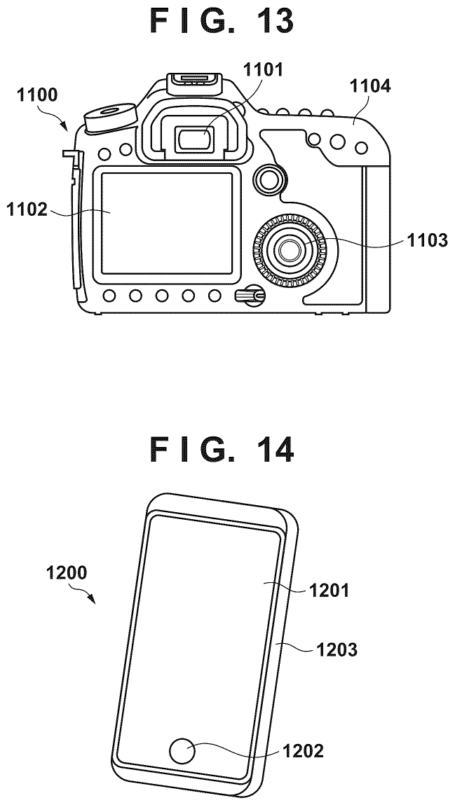

FIG. 13 is a schematic view showing an example of the photoelectric conversion device using the light emitting device 100 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 100 according to this embodiment can be applied to the viewfinder 1101 or the rear display 1102 as a display unit. In this case, the light emitting device 100 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 100 in which pixels each including the light emitting element using the organic light emitting material such as an organic EL element is arranged may be used for the viewfinder 1101 or the rear display 1102. This is so because the organic light emitting material has a high response speed. The light emitting device 100 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 100 may be applied to a display unit of an electronic apparatus. At this time, the display unit can have both a display function and an operation function. Examples of the portable terminal are a portable phone such as a smartphone, a tablet, and a head mounted display.

FIG. 14 is a schematic view showing an example of an electronic apparatus using the light emitting device 100 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 100 according to this embodiment can be applied to the display unit 1201.

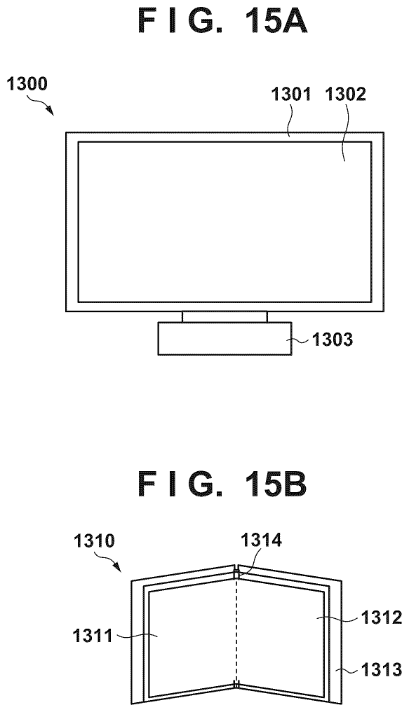

FIGS. 15A and 15B are schematic views showing examples of the display device using the light emitting device 100 according to this embodiment. FIG. 15A shows a display device such as a television monitor or a PC monitor. A display device 1300 includes a frame 1301 and a display unit 1302. The light emitting device 100 according to this embodiment can be applied to the display unit 1302. The display device 1300 can include a base 1303 that supports the frame 1301 and the display unit 1302. The base 1303 is not limited to the form shown in FIG. 15A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 15B is a schematic view showing another example of the display device using the light emitting device 100 according to this embodiment. A display device 1310 shown in FIG. 15B can be folded, and is a so-called foldable display device. The display device 1310 includes a first display unit 1311, a second display unit 1312, a housing 1313, and a bending point 1314. The light emitting device 100 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

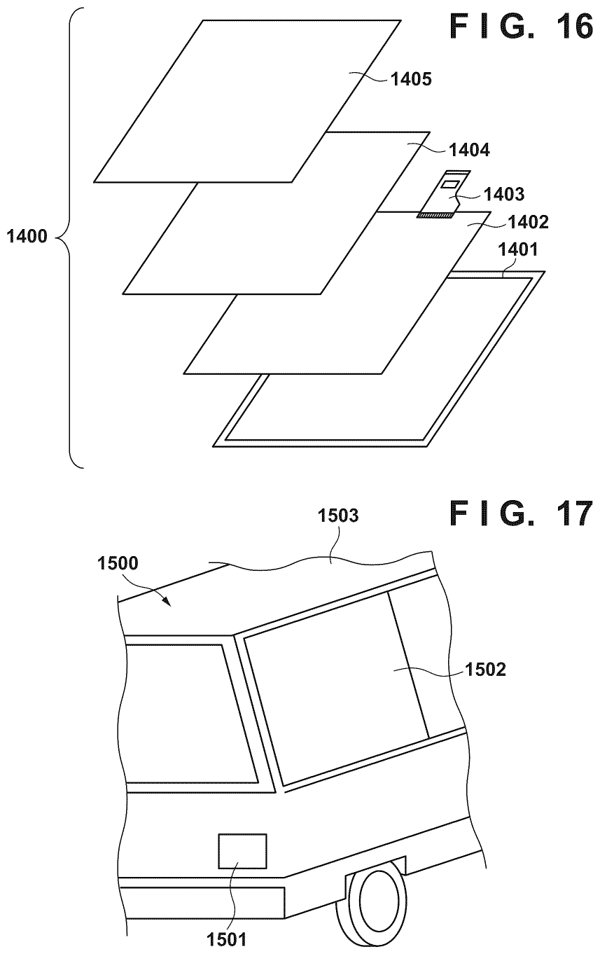

FIG. 16 is a schematic view showing an example of the illumination device using the light emitting device 100 according to this embodiment. An illumination device 1400 can include a housing 1401, a light source 1402, a circuit board 1403, an optical film 1404, and a light diffusing unit 1405. The light emitting device 100 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 100 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 17 is a schematic view of an automobile having a taillight as an example of a vehicle lighting appliance using the light emitting device 100 according to this embodiment. An automobile 1500 has a taillight 1501, and can have a form in which the taillight 1501 is turned on when performing a braking operation or the like. The light emitting device 100 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 100 according to this embodiment can be applied to the taillight 1501. The taillight 1501 can include a protection member for protecting the light emitting device 100 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 100 according to this embodiment may be used. In this case, the constituent materials of the electrodes and the like of the light emitting device 100 are formed by transparent members.

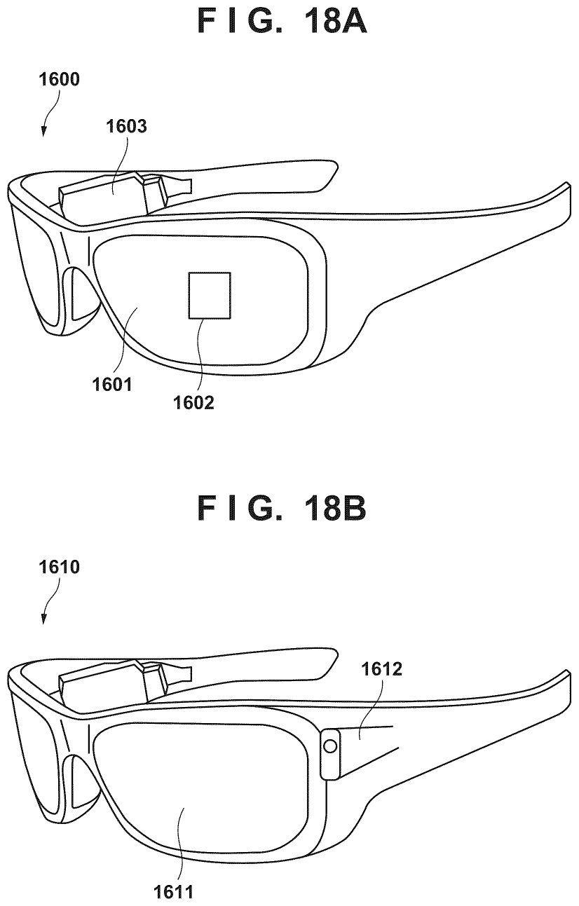

Further application examples of the light emitting device 100 according to this embodiment will be described with reference to FIGS. 18A and 18B. The light emitting device 100 can be applied to a system that can be worn as a wearable device such as smartglasses, a Head Mounted Display (TIMID), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 18A. An image capturing device 1602 such as a CMOS sensor or an SPAD is provided on the surface side of a lens 1601 of the glasses 1600. In addition, the light emitting device 100 according to this embodiment is provided on the back surface side of the lens 1601.

The glasses 1600 further include a control device 1603. The control device 1603 functions as a power supply that supplies electric power to the image capturing device 1602 and the light emitting device 100 according to each embodiment. In addition, the control device 1603 controls the operations of the image capturing device 1602 and the light emitting device 100. An optical system configured to condense light to the image capturing device 1602 is formed on the lens 1601.

Glasses 1610 (smartglasses) according to one application example will be described with reference to FIG. 18B. The glasses 1610 include a control device 1612, and an image capturing device corresponding to the image capturing device 1602 and the light emitting device 100 are mounted on the control device 1612.

The image capturing device in the control device 1612 and an optical system configured to project light emitted from the light emitting device 100 are formed in a lens 1611, and an image is projected to the lens 1611. The control device 1612 functions as a power supply that supplies electric power to the image capturing device and the light emitting device 100, and controls the operations of the image capturing device and the light emitting device 100. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 100 according to the embodiment of the present disclosure can include an image capturing device including a light receiving element, and control a displayed image based on the line-of-sight information of the user from the image capturing device.

More specifically, the light emitting device 100 decides a first visual field region at which the user is gazing and a second visual field region other than the first visual field region based on the line-of-sight information. The first visual field region and the second visual field region may be decided by the control device of the light emitting device 100, or those decided by an external control device may be received. In the display region of the light emitting device 100, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 100, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 100, the image capturing device, or an external device. If the external device holds the AI program, it is transmitted to the light emitting device 100 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-005557, filed Jan. 17, 2024, which is hereby incorporated by reference herein in its entirety.

What is claimed is:

1. A light emitting device with a plurality of light emitting elements arranged on a main surface of a substrate, wherein
each of the plurality of light emitting elements includes a light emitter and a lens, and
a surface of the lens includes a convex portion that has a convex bulge extending continuously in a direction along the main surface and has positive power, and a concave portion surrounded by the convex portion.

2. The device according to claim 1, wherein in an orthogonal projection to the main surface, the light emitter and at least a part of the convex portion are arranged to overlap each other.

3. The device according to claim 1, wherein in an orthogonal projection to the main surface, the light emitter and a portion of the convex portion where a tangent thereof is parallel to the main surface are arranged to overlap each other.

4. The device according to claim 1, wherein a length between an outer edge of the lens and the main surface is larger than a length between the main surface and a portion of the concave portion that is closest to the main surface.

5. The device according to claim 4, wherein a maximum angle of the surface with respect to the main surface between a portion of the convex portion where a tangent thereof is parallel to the main surface and the outer edge of the lens is smaller than a maximum angle of the surface with respect to the main surface between the parallel portion and the portion of the concave portion that is closest to the main surface.

6. The device according to claim 1, wherein in an orthogonal projection to the main surface, each of the plurality of light emitting elements further includes a non-light emitting portion surrounded by the light emitter.

7. The device according to claim 6, wherein in the orthogonal projection to the main surface, the light emitter and a portion of the concave portion that is closest to the main surface do not overlap each other.

8. The device according to claim 6, wherein in the orthogonal projection to the main surface, the non-light emitting portion and a portion of the concave portion that is closest to the main surface overlap each other.

9. The device according to claim 1, wherein in an orthogonal projection to the main surface, the light emitter and an outer edge of the lens do not overlap each other.

10. The device according to claim 1, wherein
a medium layer is arranged between the light emitter and the lens, and
a refractive index of the medium layer is not less than a refractive index of the lens.

11. The device according to claim 10, wherein
the medium layer is a first medium layer,
a second medium layer is arranged between the light emitter and the first medium layer, and
a refractive index of the first medium layer is not more than a refractive index of the second medium layer.

12. The device according to claim 1, wherein
when a position where an angle of the surface with respect to the main surface is maximum between a portion of the convex portion where a tangent thereof is parallel to the main surface and an outer edge of the lens is a first position, and a position in the light emitter where light to be transmitted through the first position and extracted in a direction perpendicular to the main surface is emitted is a second position,
in an orthogonal projection to the main surface, a length between the first position and the second position is larger than a length between the first position and an outer edge of the light emitter.

13. The device according to claim 1, wherein in an orthogonal projection to the main surface, a length between a center of the light emitter and a portion of the convex portion where a tangent thereof is parallel to the main surface is larger than a length between the center and a portion of the concave portion that is closest to the main surface.

14. The device according to claim 1, wherein
the convex portion is a first convex portion,
the surface further includes a second convex portion surrounded by the concave portion and protruding in a direction away from the main surface, and
the light emitter and at least a part of the second convex portion are arranged to overlap each other.

15. The device according to claim 1, wherein
when a position where an angle of the surface with respect to the main surface is maximum between a portion of the convex portion where a tangent thereof is parallel to the main surface and an outer edge of the lens is a first position, and a position where an angle of the surface with respect to the main surface is maximum between the parallel portion and the concave portion is a third position,
from the parallel portion to the first position, the angle of the surface with respect to the main surface increases in one of a continuous manner and a stepwise manner,
from the parallel portion to the third position, the angle of the surface with respect to the main surface increases in one of a continuous manner and a stepwise manner, and
from a portion of the concave portion that is closest to the main surface to the third position, the angle of the surface with respect to the main surface increase in one of a continuous manner and a stepwise manner.

16. A light emitting device with a plurality of light emitting elements arranged on a main surface of a substrate, wherein
each of the plurality of light emitting elements includes a light emitter and a lens, and
a surface of the lens includes a convex portion that has a convex bulge extending continuously in a direction along the main surface and has positive power, and a first concave portion and a second concave portion adjacent to each other via the convex portion,
a maximum angle of the surface with respect to the main surface between a portion of the convex portion where a tangent thereof is parallel to the main surface and a portion of the second concave portion that is closest to the main surface is smaller than a maximum angle of the surface with respect to the main surface between the parallel portion and a portion of the first concave portion that is closest to the main surface, and
in an orthogonal projection to the main surface, the first concave portion is arranged at a position closer to a center of the light emitter than the second concave portion.

17. An image forming device comprising a photosensitive member, an exposure light source configured to expose the photosensitive member, a developing device configured to apply a developing agent to the exposed photosensitive member, and a transfer device configured to transfer an image developed by the developing device to a print medium,
wherein the exposure light source includes the light emitting device according to claim 1.

18. A display device comprising the light emitting device according to claim 1, and an active element connected to the light emitting device.

19. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

20. An electronic apparatus comprising a housing provided with a display unit, and a communication unit provided in the housing and configured to perform external communication,
wherein the display unit includes the light emitting device according to claim 1.
